(19) United States
(12) Patent Application Publication
(10) Pub. No.: US 2026/0248032 A1
(43) Pub. Date: Aug. 20, 2026

(54) SEMICONDUCTOR DEVICE

(71) Applicant: Mitsubishi Electric Corporation, Tokyo (JP)

(72) Inventors: Takuya KITABAYASHI, Tokyo (JP); Naoki YOSHIMATSU, Tokyo (JP); Hiroyuki MASUMOTO, Tokyo (JP)

(73) Assignee: Mitsubishi Electric Corporation, Tokyo (JP)

(21) Appl. No.: 19/161,587

(22) PCT Filed: Jun. 8, 2023
(86) PCT No.: PCT/JP2023/021307

§ 371 Date: Sep. 2, 2025

(51) Int. Cl. H10W 76/63; H10D 80/20; H10D 80/30; H10W 40/20; H10W 70/20; H10W 76/67; H10W 90/00

(52) U.S. Cl. CPC H10W 76/63; H10D 80/231; H10D 80/251; H10D 80/30; H10W 70/20; H10W 76/67; H10W 90/734; H10W 40/235

(57) ABSTRACT

A semiconductor device includes a semiconductor element, a first electrode, a second electrode, and a sealing material. The first electrode includes a first side surface and a first upper surface. The first side surface protrudes from an outer peripheral upper surface forming an outer peripheral portion of the sealing material and faces the second electrode. The first upper surface is exposed from the sealing material. The second electrode includes a second side surface and a second upper surface. The second side surface protrudes from the outer peripheral upper surface forming the outer peripheral portion of the sealing material and faces the first electrode. The second upper surface is exposed from the sealing material. The first side surface and the second side surface are covered with the sealing material. The sealing material includes at least either a recess portion or a protrusion portion between the first electrode and the second electrode.

### TECHNICAL FIELD

The present disclosure relates to a semiconductor device.

### BACKGROUND ART

A semiconductor device is required to achieve high heat dissipation. In a semiconductor device described in Patent Document 1, a main terminal and a control terminal are exposed from a flush surface of an upper portion of a sealing resin body to achieve improved heat dissipation.

### PRIOR ART DOCUMENT

### Patent Document

Patent Document 1: Japanese Patent Application Laid-Open No. 2014-157927

### SUMMARY

### Problem to be Solved by the Invention

A semiconductor device is required to achieve not only high heat dissipation but also low inductance for loss reduction. Although reducing a distance between electrodes is effective for achieving low inductance, reducing the distance between the electrodes leads to a problem in securing insulation between the electrodes.

To solve such issues as described above, an object of the present disclosure is to provide a semiconductor device that achieves high insulation and low inductance.

### Means to Solve the Problem

A semiconductor device according to the present disclosure includes a semiconductor element, a first electrode, a second electrode, and a sealing material. The first electrode is electrically connected to the semiconductor element. The second electrode is provided to be adjacent to the first electrode and is electrically connected to the semiconductor element. The sealing material seals the semiconductor element, an area other than an upper surface of the first electrode, and an area other than an upper surface of the second electrode. The first electrode includes a first side surface and a first upper surface. The first side surface protrudes from an outer peripheral upper surface forming an outer peripheral portion of the sealing material and faces the second electrode. The first upper surface is exposed from the sealing material. The second electrode includes a second side surface and a second upper surface. The second side surface protrudes from the outer peripheral upper surface forming the outer peripheral portion of the sealing material and faces the first electrode. The second upper surface is exposed from the sealing material. The first side surface and the second side surface are covered with the sealing material. The sealing material includes at least either a recess portion or a protrusion portion between the first electrode and the second electrode.

### Effects of the Invention

According to the present disclosure, a semiconductor device that achieves high insulation and low inductance is provided.

Objects, features, aspects, and advantages of the present disclosure will become more apparent from the following detailed description and the accompanying drawings.

### BRIEF DESCRIPTION OF DRAWINGS

FIG. 1 is a cross-sectional view illustrating a configuration of a semiconductor device according to a first embodiment.

FIG. 2 is a cross-sectional view illustrating a configuration of a semiconductor device according to a second embodiment.

FIG. 3 is a cross-sectional view illustrating a configuration of a semiconductor device according to a third embodiment.

FIG. 4 is a cross-sectional view illustrating a configuration of a semiconductor device according to a fourth embodiment.

FIG. 5 is a cross-sectional view illustrating a configuration of a semiconductor device according to a fifth embodiment.

FIG. 6 is a plan view illustrating a configuration of a semiconductor device according to a sixth embodiment.

FIG. 7 is a cross-sectional view illustrating the configuration of the semiconductor device according to the sixth embodiment.

FIG. 8 is a plan view illustrating a configuration of a semiconductor device according to a seventh embodiment.

FIG. 9 is a cross-sectional view illustrating the configuration of the semiconductor device according to the seventh embodiment.

### DESCRIPTION OF EMBODIMENTS

### First Embodiment

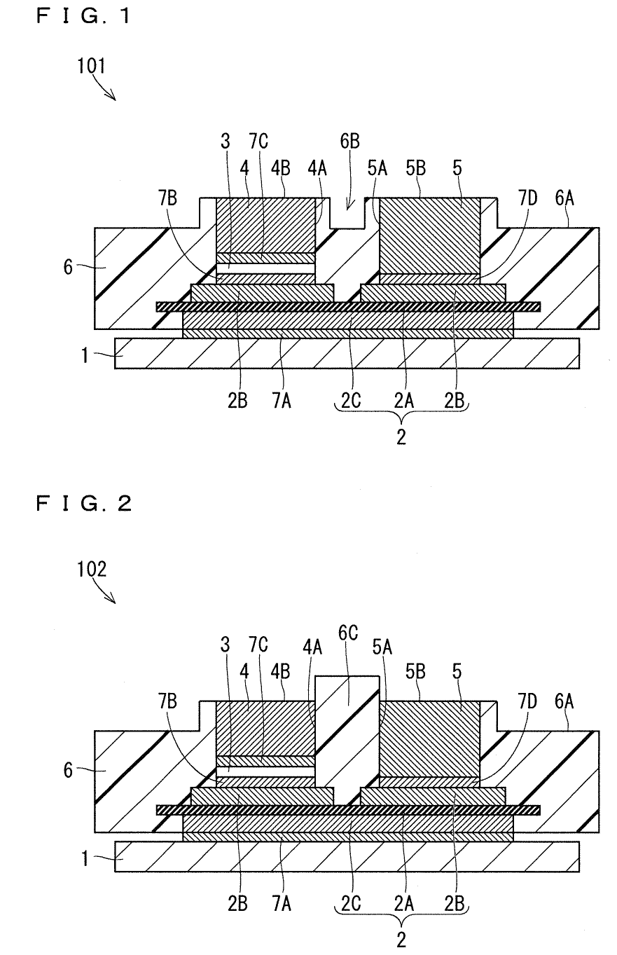

FIG. 1 is a cross-sectional view illustrating a configuration of a semiconductor device 101 according to a first embodiment.

The semiconductor device 101 includes a heat dissipation substrate 1, an insulating substrate 2, a semiconductor element 3, a first electrode 4, a second electrode 5, and a sealing material 6.

The heat dissipation substrate 1 is a plate including, for example, metal such as copper or aluminum. The heat dissipation substrate 1 has a function of transmitting heat generated in an electronic component such as the semiconductor element 3 to outside.

The insulating substrate 2 is provided on the heat dissipation substrate 1. The insulating substrate 2 includes an insulating layer 2A, a front circuit pattern 2B, and a back circuit pattern 2C. The insulating layer 2A includes, for example, ceramic. The front circuit pattern 2B is provided on an upper surface of the insulating layer 2A. The back circuit pattern 2C is provided to a lower surface of the insulating layer 2A. The front circuit pattern 2B and the back circuit pattern 2C include a conductive material such as metal. The back circuit pattern 2C is bonded to the heat dissipation substrate 1 via a bonding material 7A. The bonding material 7A is, for example, solder, a brazing material, or a sintered material.

The semiconductor element 3 is held above the insulating substrate 2. The semiconductor element 3 according to the first embodiment is a vertical semiconductor element through which a current flows between its upper surface and its lower surface, and includes a front electrode (not illustrated) and a back electrode (not illustrated). The back electrode of the semiconductor element 3 is bonded to the front circuit pattern 2B of the insulating substrate 2 via a bonding material 7B. The bonding material 7B is a conductive material such as solder. The semiconductor element 3 includes, for example, semiconductor such as Si. The semiconductor element 3 preferably includes so-called wide bandgap semiconductor such as SiC, GaN, Ga₂O₃, or diamond. The semiconductor element 3 includes, for example, a power semiconductor element and a control integrated circuit (IC) for controlling the power semiconductor element. The semiconductor element 3 includes, for example, an insulated gate bipolar transistor (IGBT) or a metal oxide semiconductor field effect transistor (MOSFET) and a Schottky barrier diode. Alternatively, the semiconductor element 3 may include a reverse-conducting IGBT (RC-IGBT) in which an IGBT and a freewheeling diode are formed in one semiconductor substrate.

The first electrode 4 is provided to be adjacent to the second electrode 5. The first electrode 4 is electrically connected to the semiconductor element 3 inside the sealing material 6. In the first embodiment, a lower surface of the first electrode 4 is bonded to the front electrode of the semiconductor element 3 via a bonding material 7C. The front electrode of the semiconductor element 3 is, for example, an emitter electrode. The first electrode 4 protrudes upward higher than an outer peripheral upper surface 6A forming an outer peripheral portion of the sealing material 6. The first electrode 4 includes a first side surface 4A and a first upper surface 4B. The first side surface 4A protrudes from the outer peripheral upper surface 6A of the sealing material 6 and faces the second electrode 5. The first side surface 4A is covered with the sealing material 6. In the first embodiment, the first side surface 4A is wholly covered with the sealing material 6. The first upper surface 4B is not covered with the sealing material 6 and is exposed from an opening provided to the sealing material 6. The first electrode 4 is not limited in shape. The first electrode 4 has, for example, a block shape. The block shape is, for example, a quadrangular prism, a cylinder, or a U-letter shape.

The second electrode 5 is provided to be adjacent to the first electrode 4. The second electrode 5 is electrically connected to the semiconductor element 3 inside the sealing material 6. In the first embodiment, a lower surface of the second electrode 5 is bonded to the front circuit pattern 2B via a bonding material 7D. The front circuit pattern 2B is electrically connected to, for example, a collector electrode that is the back electrode of the semiconductor element 3. The front circuit pattern 2B may be electrically connected to a control electrode such as a gate electrode of the semiconductor element 3 or a sensing electrode. The second electrode 5 protrudes upward higher than the outer peripheral upper surface 6A forming the outer peripheral portion of the sealing material 6. The second electrode 5 includes a second side surface 5A and a second upper surface 5B. The second side surface 5A protrudes from the outer peripheral upper surface 6A of the sealing material 6 and faces the first electrode 4. The second side surface 5A is covered with the sealing material 6. In the first embodiment, the second side surface 5A is wholly covered with the sealing material 6. The second upper surface 5B is not covered with the sealing material 6 and is exposed from an opening provided to the sealing material 6. The second electrode 5 is not limited in shape. The second electrode 5 has, for example, a block shape. The block shape is, for example, a quadrangular prism, a cylinder, or a U-letter shape.

The sealing material 6 seals the insulating substrate 2, the semiconductor element 3, an area other than the upper surface of the first electrode 4, and an area other than the upper surface of the second electrode 5. The sealing material 6 according to the first embodiment includes a recess portion 6B between the first electrode 4 and the second electrode 5. A bottom surface of the recess portion 6B is provided at a position lower than positions of the first upper surface 4B of the first electrode 4 and the second upper surface 5B of the second electrode 5. The sealing material 6 includes a resin having an insulation property. The sealing material 6 is, for example, a silicone resin or an epoxy resin.

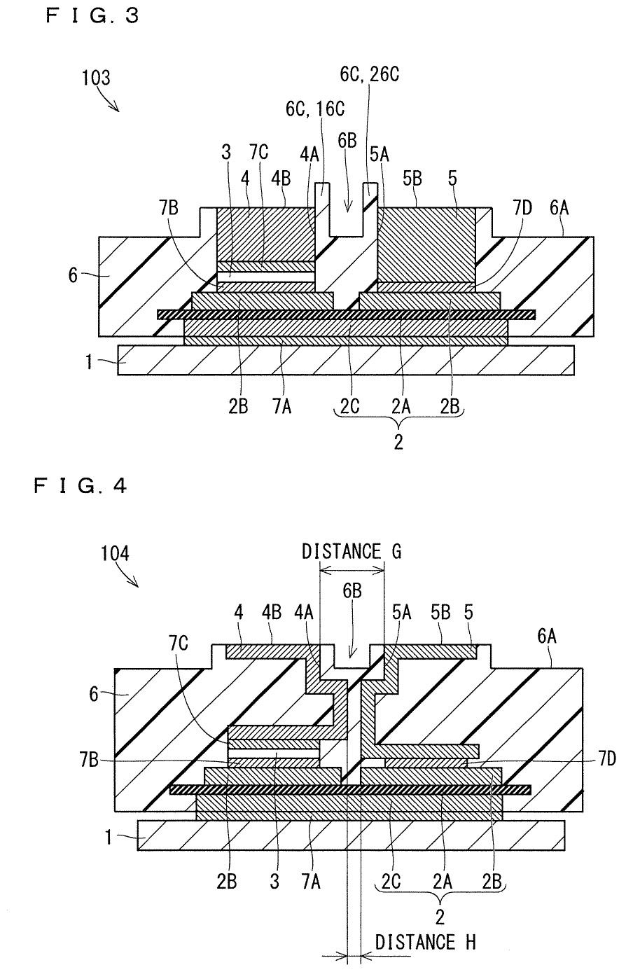

To summarize those described above, the semiconductor device 101 according to the first embodiment includes the semiconductor element 3, the first electrode 4, the second electrode 5, and the sealing material 6. The first electrode 4 is electrically connected to the semiconductor element 3. The second electrode 5 is provided to be £ adjacent to the first electrode 4 and is electrically connected to the semiconductor element 3. The sealing material 6 seals the semiconductor element 3, the area other than the upper surface of the first electrode 4, and the area other than the upper surface of the second electrode 5. The first electrode 4 includes the first side surface 4A and the first upper surface 4B. The first side surface 4A protrudes from the outer peripheral upper surface 6A forming the outer peripheral portion of the sealing material 6 and faces the second electrode 5. The first upper surface 4B is exposed from the sealing material 6. The second electrode 5 includes the second side surface 5A and the second upper surface 5B. The second side surface 5A protrudes from the outer peripheral upper surface 6A forming the outer peripheral portion of the sealing material 6 and faces the first electrode 4. The second upper surface 5B is exposed from the sealing material 6. The first side surface 4A and the second side surface 5A are covered with the sealing material 6. The sealing material 6 includes at least either the recess portion 6B or a protrusion portion 6C (see FIG. 2 and FIG. 3) between the first electrode 4 and the second electrode 5.

In the semiconductor device 101 as described above, a creeping distance between the first electrode 4 and the second electrode 5 is longer than a spatial distance between the first electrode 4 and the second electrode 5. The creeping distance corresponds to, for example, a distance from an end of the first upper surface 4B to an end of the second upper surface 5B via a surface of the sealing material 6. The spatial distance corresponds to, for example, a linear distance from the end of the first upper surface 4B to the end of the second upper surface 5B. Since the creeping distance is longer than the spatial distance, insulation is secured even if the spatial distance is reduced. Since mutual cancellation in inductance occurs as the spatial distance is reduced, the semiconductor device 101 is decreased in inductance. As described above, the semiconductor device 101 achieves high insulation and low inductance. The semiconductor device 101 is configured to be applied to various products and power systems including, for example, a power supply and a power source.

Instead of the insulating substrate 2 according to the first embodiment, one component (not illustrated) in which the insulating layer 2A and the heat dissipation substrate 1 are integrated may be applied. In this case, the heat dissipation substrate 1 includes the insulating layer 2A formed on an upper surface of heat dissipation substrate 1 and the front circuit pattern 2B formed on the insulating layer 2A. In this case, there is no bonding material between the insulating layer 2A and the heat dissipation substrate 1. The insulating layer 2A includes, for example, a resin.

### Second Embodiment

In a second embodiment, components similar or identical to those in the first embodiment are denoted by identical reference numerals, and the detailed description thereof will be omitted.

FIG. 2 is a cross-sectional view illustrating a configuration of a semiconductor device 102 according to the second embodiment. The sealing material 6 includes a protrusion portion 6C between the first electrode 4 and the second electrode 5. As the protrusion portion 6C according to the second embodiment, the sealing material 6 between the first electrode 4 and the second electrode 5 protrudes upward. An upper surface of the protrusion portion 6C is provided at a position higher than the positions of the first upper surface 4B of the first electrode 4 and the second upper surface 5B of the second electrode 5.

The semiconductor device 102 as described above achieves low inductance due to a reduced spatial distance between the first electrode 4 and the second electrode 5 and improved insulation due to an increased creeping distance.

### Third Embodiment

In a third embodiment, components similar or identical to those in the first or second embodiment are denoted by identical reference numerals, and the detailed description thereof will be omitted.

FIG. 3 is a cross-sectional view illustrating a configuration of a semiconductor device 103 according to the third embodiment. The sealing material 6 includes the recess portion 6B and the protrusion portion 6C between the first electrode 4 and the second electrode 5. The protrusion portion 6C of the sealing material 6 includes a first protrusion portion 16C and a second protrusion portion 26C. The first protrusion portion 16C covers the first side surface 4A and protrudes upward higher than the first upper surface 4B. The second protrusion portion 26C covers the second side surface 5A and protrudes upward higher than the second upper surface 5B. In the third embodiment, only the first protrusion portion 16C and the second protrusion portion 26C protrude upward higher than the first electrode 4 and the second electrode 5. The recess portion 6B of the sealing material 6 is provided between the first protrusion portion 16C and the second protrusion portion 26C. The bottom surface of the recess portion 6B is provided at a position lower than the positions of the first upper surface 4B of the first electrode 4 and the second upper surface 5B of the second electrode 5.

The semiconductor device 103 as described above achieves low inductance due to a reduced spatial distance between the first electrode 4 and the second electrode 5 and improved insulation due to an increased creeping distance.

### Fourth Embodiment

In a fourth embodiment, components similar or identical to those in any one of the first to third embodiments are denoted by identical reference numerals, and the detailed description thereof will be omitted.

FIG. 4 is a cross-sectional view illustrating a configuration of a semiconductor device 104 according to the fourth embodiment. The first electrode 4 and the second electrode 5 include plate materials each having a plurality of bent portions inside the sealing material 6. An inter-electrode distance H between the first electrode 4 and the second electrode 5 inside the sealing material 6 is shorter than a distance G between the end of the first upper surface 4B and the end of the second upper surface 5B. The inter-electrode distance H according to the fourth embodiment is a shortest distance between the first electrode 4 and the second electrode 5 inside the sealing material 6. Similarly, the distance G according to the fourth embodiment is a shortest distance between the end of the first upper surface 4B and the end of the second upper surface 5B. The sealing material 6 includes the recess portion 6B between the first electrode 4 and the second electrode 5. The bottom surface of the recess portion 6B is provided at a position lower than the positions of the first upper surface 4B and the second upper surface 5B.

The semiconductor device 104 as described above achieves low inductance due to a reduced spatial distance between the first electrode 4 and the second electrode 5 and improved insulation due to an increased creeping distance.

### Fifth Embodiment

In a fifth embodiment, components similar or identical to those in any one of the first to fourth embodiments are denoted by identical reference numerals, and the detailed description thereof will be omitted.

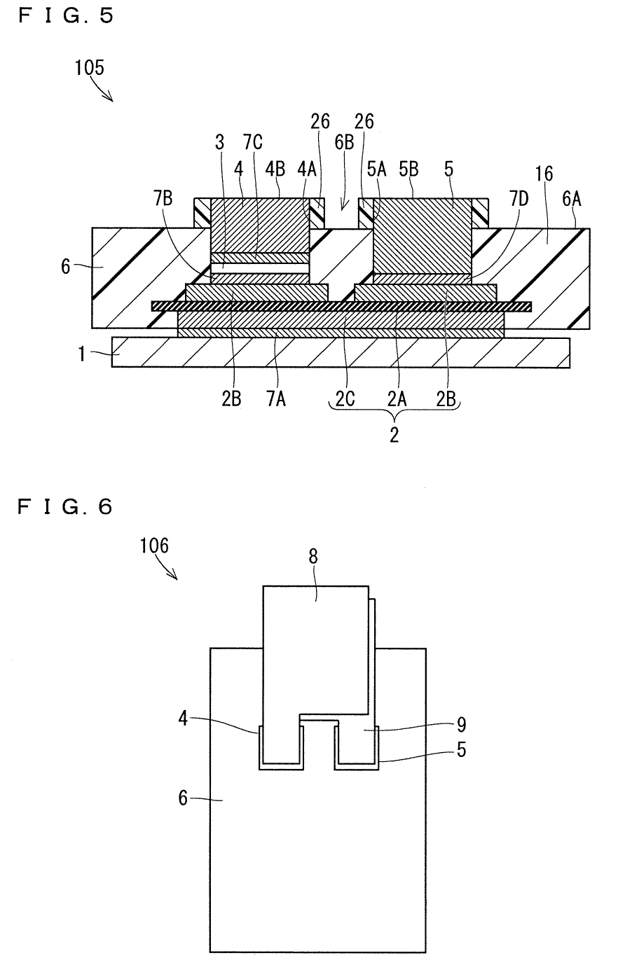

FIG. 5 is a cross-sectional view illustrating a configuration of a semiconductor device 105 according to the fifth embodiment. The sealing material 6 includes a first sealing material 16 and a second sealing material 26. The first sealing material 16 seals the insulating substrate 2, the semiconductor element 3, a lower portion of the first electrode 4, and a lower portion of the second electrode 5. The second sealing material 26 covers the first side surface 4A of the first electrode 4 and the second side surface 5A of the second electrode 5. The second sealing material 26 includes a resin having an insulation property. The second sealing material 26 is, for example, an epoxy resin.

The semiconductor device 105 as described above achieves low inductance due to a reduced spatial distance between the first electrode 4 and the second electrode 5 and improved insulation due to an increased creeping distance.

### Sixth Embodiment

In a sixth embodiment, components similar or identical to those in any one of the first to fifth embodiments are denoted by identical reference numerals, and the detailed description thereof will be omitted.

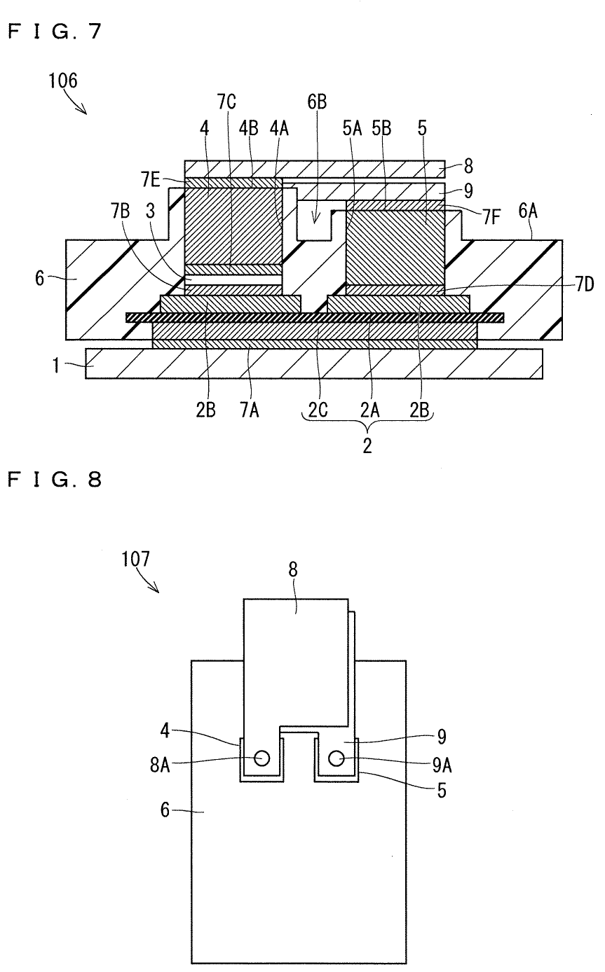

FIG. 6 is a plan view illustrating a configuration of a semiconductor device 106 according to the sixth embodiment. FIG. 7 is a cross-sectional view illustrating the configuration of the semiconductor device 106 according to the sixth embodiment. The semiconductor device 106 includes a first bus bar 8 and a second bus bar 9, in addition to the heat dissipation substrate 1, the insulating substrate 2, the semiconductor element 3, the first electrode 4, the second electrode 5, and the sealing material 6.

A height of the first upper surface 4B from the outer peripheral upper surface 6A of the sealing material 6 is different from a height of the second upper surface 5B from the outer peripheral upper surface 6A of the sealing material 6. The first upper surface 4B according to the sixth embodiment is provided at a position higher than the position of the second upper surface 5B. The first side surface 4A and the second side surface 5A are covered with the sealing material 6. The sealing material 6 includes the recess portion 6B between the first electrode 4 and the second electrode 5.

The first bus bar 8 has a flat plate shape. The first bus bar 8 is bonded to the first upper surface 4B of the first electrode 4 via a bonding material 7E. The second bus bar 9 has a flat plate shape. The second bus bar 9 is bonded to the second upper surface 5B of the second electrode 5 via a bonding material 7F. The first bus bar 8 and the second bus bar 9 are provided to be parallel to and overlapped with each other at an interval. The first bus bar 8 and the second bus bar 9 according to the sixth embodiment are parallel flat plates. The first bus bar 8 and the second bus bar 9 are connected to a power system outside the semiconductor device 106.

In the semiconductor device 106 as described above, it is not necessary to prepare a first bus bar and a second bus bar each having a bent portion. Since the first bus bar 8 and the second bus bar 9 may be parallel flat plates, it is possible to design at high accuracy a clearance between the first bus bar 8 and the second bus bar 9. Since the first bus bar 8 and the second bus bar 9 are parallel flat plates, a power system including the semiconductor device 106 wholly decreases in inductance.

Along with increased electric-current density in the semiconductor device 106, the first bus bar 8 and the second bus bar 9 have been increased in thickness. When the first bus bar 8 and the second bus bar 9 each have a bent portion, it is difficult to control a mutual distance. The first bus bar 8 and the second bus bar 9, which are parallel flat plates as described above, are effective.

The sealing material 6 illustrated in FIG. 7 may include a protrusion portion, in addition to the recess portion 6B. For example, the protrusion portion is provided inside the recess portion 6B. For a height of the protrusion portion, the height does not allow contact with the first bus bar 8 and the second bus bar 9. When a region between the first electrode 4 and the second electrode 5 is not covered with the first bus bar 8 and the second bus bar 9, different from those illustrated in FIG. 7, the height of the protrusion portion may be higher than the height of at least either the first upper surface 4B or the second upper surface 5B.

### Seventh Embodiment

In a seventh embodiment, components similar or identical to those in any one of the first to sixth embodiments are denoted by identical reference numerals, and the detailed description thereof will be omitted.

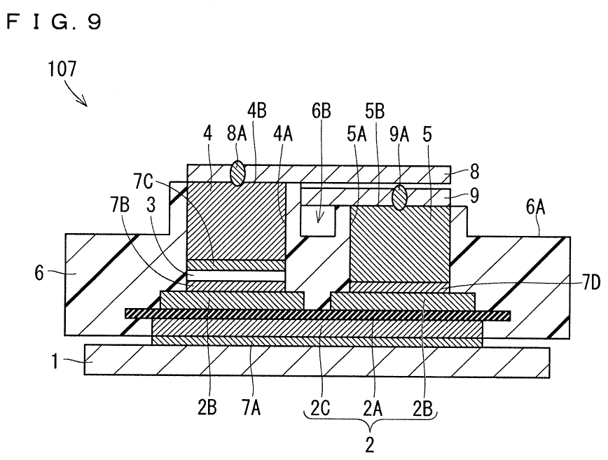

FIG. 8 is a plan view illustrating a configuration of a semiconductor device 107 according to the seventh embodiment. FIG. 9 is a cross-sectional view illustrating the configuration of the semiconductor device 107 according to the seventh embodiment. A basic configuration of the semiconductor device 107 is similar or identical to that of the semiconductor device 106 illustrated in the sixth embodiment. In the semiconductor device 107, the first bus bar 8 has a welding mark 8A. The welding mark 8A is formed on a bonding portion between the first bus bar 8 and the first upper surface 4B of the first electrode 4. Similarly, the second bus bar 9 has a welding mark 8B. The welding mark 8B is formed on a bonding portion between the second bus bar 9 and the second upper surface 5B of the second electrode 5.

When bonding materials 7E and 7F such as solder are used for bonding the electrodes and the bus bars, the bonding materials become different in volume before and after curing. Therefore, it is difficult to control a clearance between the first bus bar 8 and the second bus bar 9. By using welding for bonding each of the electrodes and each of the bus bars, the clearance between the first bus bar 8 and the second bus bar 9 is controlled at high accuracy.

Although the present disclosure has been described in detail, the above description is illustrative and not restrictive in all aspects. It is understood that it is possible to assume numerous non-illustrated modifications.

Note that it is possible to freely combine the embodiments, and it is possible to appropriately make modifications and omissions in the embodiments.

### EXPLANATION OF REFERENCE SIGNS

1 heat dissipation substrate, 2 insulating substrate, 2A insulating layer, 2B front circuit pattern, 2C back circuit pattern, 3 semiconductor element, 4 first electrode, 4A first side surface, 4B first upper surface, 5 second electrode, 5A second side surface, 5B second upper surface, 6 sealing material, 6A outer peripheral upper surface, 6B recess portion, 6C protrusion portion, 7A to 7F bonding material, 8 first bus bar, 8A welding mark, 8B welding mark, 9 second bus bar, 16 first sealing material, 16C first protrusion portion, 26 second sealing material, 26C second protrusion portion, 101 to 107 semiconductor device, G distance, H inter-electrode distance.

1. A semiconductor device comprising:
a semiconductor element;
a first electrode electrically connected to the semiconductor element;
a second electrode provided to be adjacent to the first electrode and electrically connected to the semiconductor element; and
a sealing material sealing the semiconductor element, an area other than an upper surface of the first electrode, and an area other than an upper surface of the second electrode, wherein
the first electrode includes a first side surface protruding from an outer peripheral upper surface forming an outer peripheral portion of the sealing material and facing the second electrode and a first upper surface that is the upper surface exposed from the sealing material,
the second electrode includes a second side surface protruding from the outer peripheral upper surface of the sealing material and facing the first electrode and a second upper surface that is the upper surface exposed from the sealing material,
the first side surface and the second side surface are covered with the sealing material, and
the sealing material includes at least either a recess portion or a protrusion portion between the first electrode and the second electrode.

2. The semiconductor device according to claim 1, wherein a bottom surface of the recess portion of the sealing material is provided at a position lower than positions of the first upper surface and the second upper surface.

3. The semiconductor device according to claim 1, wherein an upper surface of the protrusion portion of the sealing material is provided at a position higher than the positions of the first upper surface and the second upper surface.

4. The semiconductor device according to claim 1, wherein
the protrusion portion of the sealing material includes a first protrusion portion that covers the first side surface and protrudes upward higher than the first upper surface and a second protrusion portion that covers the second side surface and protrudes upward higher than the second upper surface, and
the recess portion of the sealing material is provided between the first protrusion portion and the second protrusion portion.

5. The semiconductor device according to claim 1, wherein an inter-electrode distance between the first electrode and the second electrode inside the sealing material is shorter than a distance between an end of the first upper surface and an end of the second upper surface.

6. The semiconductor device according to claim 1, wherein
the sealing material includes a first sealing material that seals the semiconductor element and a second sealing material that covers the first side surface of the first electrode and the second side surface of the second electrode, and
the second sealing material is a resin having an insulation property.

7. The semiconductor device according to claim 1, wherein a height of the first upper surface of the first electrode from the outer peripheral upper surface of the sealing material is different from a height of the second upper surface of the second electrode from the outer peripheral upper surface of the sealing material.

8. The semiconductor device according to claim 7,
further comprising a first bus bar having a flat plate shape and bonded to the first upper surface of the first electrode and a second bus bar having a flat plate shape and bonded to the second upper surface of the second electrode,
wherein the first bus bar and the second bus bar are provided to be parallel to and overlapped with each other at an interval.

9. The semiconductor device according to claim 8, wherein
the first bus bar has a welding mark at a bonding portion between the first bus bar and the first upper surface, and
the second bus bar has a welding mark at a bonding portion between the second bus bar and the second upper surface.

10. The semiconductor device according to claim 1, wherein the sealing material covers the first side surface of the first electrode wholly and the second side surface of the second electrode wholly.
